(19) United States
(12) Patent Application Publication
(10) Pub. No.: US 2024/0203713 A1
(43) Pub. Date: Jun. 20, 2024

(54) IN-SITU DIAGNOSIS OF PLASMA SYSTEM

(71) Applicant: Tokyo Electron Limited, Tokyo (JP)

(72) Inventors: Barton Lane, Austin, TX (US); Jun Shinagawa, Fremont, CA (US); Merritt Funk, Austin, TX (US); Yohei Yamazawa, Tokyo (JP)

(21) Appl. No.: 18/066,078

(22) Filed: Dec. 14, 2022

(51) Int. Cl. H01J 37/32

(52) U.S. Cl. CPC H01J 37/32972; H01J 37/32082; H01J 37/3244; H01J 2237/332; H01J 2237/3341; H01J 2237/335

(57) ABSTRACT

A method for processing a substrate that includes: processing a series of substrates using a plasma processing system having a plasma processing chamber by reactive ion etching (RIE) according to a RIE process condition; and after the processing, performing an in-situ diagnosis of the plasma processing system, the in-situ diagnosis including loading a substrate in the plasma processing chamber, depositing a film over the substrate, purging the plasma processing chamber with an inert gas, generating a RF plasma in the plasma processing chamber from the inert gas, sputtering the film to generate an etch product, the sputtering including exposing the substrate to the RF plasma, determining a rate of the sputtering of the film, and based on the rate of the sputtering of the film, determining a usability condition of the plasma processing system for processing another substrate.

### TECHNICAL FIELD

The present invention relates generally to methods of characterizing a plasma system, and, in particular embodiments, to in-situ diagnosis of plasma system.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

Advanced process control that involves process and system characterization and fault detection in semiconductor manufacturing is essential for reproducible production of complex structures. Especially in high-volume manufacturing, plasma system diagnosis is of paramount importance for process consistency. As the minimum dimension of features in a patterned layer has shrunk periodically and new materials have been introduced in ICs, the need for improved plasma system diagnosis to assure process compliance and cost reduction has increased.

### SUMMARY

In accordance with an embodiment of the present invention, a method for processing a substrate that includes: processing a series of substrates using a plasma processing system having a plasma processing chamber by reactive ion etching (RIE) according to a RIE process condition; and after the processing, performing an in-situ diagnosis of the plasma processing system, the in-situ diagnosis including loading a substrate in the plasma processing chamber, depositing a film over the substrate, purging the plasma processing chamber with an inert gas, generating a RF plasma in the plasma processing chamber from the inert gas, sputtering the film to generate an etch product, the sputtering including exposing the substrate to the RF plasma, determining a rate of the sputtering of the film, and based on the rate of the sputtering of the film, determining a usability condition of the plasma processing system for processing another substrate.

In accordance with an embodiment of the present invention, a method for processing a substrate that includes: performing plasma processes to process a set of substrates using a RF plasma processing system having a plasma processing chamber and a RF power delivery system, the plasma processes are temporally separated to each other by intervals; during some of the intervals, periodically repeating an optical emission spectroscopy (OES) analysis, each OES analysis including depositing a film over a substrate loaded in the plasma processing chamber, sputtering the film by exposing the substrate to a plasma generated from an inert gas, and while exposing the substrate to the plasma, collecting a series of OES data, where repeating the OES analysis generates a plurality of the series of OES data, and comparing the plurality of the series of OES data to characterize a change in a usability condition of the RF plasma processing system during the plasma processes.

In accordance with an embodiment of the present invention, a method for processing a substrate that includes: processing a series of substrates in a plasma processing chamber by reactive ion etching (RIE) according to a RIE process condition; and after the processing, performing an in-situ diagnosis of the plasma processing chamber, the in-situ diagnosis including providing a baseline rate of sputtering for the plasma processing chamber, loading a substrate in the plasma processing chamber, forming a surface oxide film over the substrate, generating a RF plasma in the plasma from a gas including an inert gas according to a diagnostic process condition, sputtering the surface oxide film, the sputtering including exposing the substrate to the RF plasma, while sputtering the surface oxide film, performing spectroscopic measurements to determine an actual rate of the sputtering of the surface oxide film, and based on a variance between the baseline rate of sputtering and the actual rate of sputtering, determining a usability condition of the plasma processing chamber for processing another substrate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example plasma processing system with an optical emission spectroscopy (OES) configured to perform an in-situ diagnosis in accordance with various embodiments;

FIGS. 2A-2C illustrate cross-sectional views of an example substrate during an in-situ diagnosis comprising in accordance with various embodiments, wherein FIG. 2A illustrates an incoming blank substrate, FIG. 2B illustrates the blank substrate after depositing a film, and FIG. 2C illustrates the blank substrate after sputtering the film;

FIGS. 3A and 3B illustrate example temporal profiles of OES signals during an in-situ diagnosis in accordance with one embodiment, wherein FIG. 3A illustrates the profile of Si signal, and FIG. 3B illustrates the profile of O signal;

FIG. 4 illustrates an example timing diagram of repeated in-situ diagnosis during the usage of a plasma processing chamber for plasma processes; and

FIGS. 5A-5C illustrate process flow charts of methods of in-situ diagnosis in accordance with various embodiments, wherein FIG. 5A illustrates an embodiment, FIG. 5B illustrates another embodiment, and FIG. 5C illustrates an alternate embodiment.

### DETAILED DESCRIPTION OF ILLUSTRATIVE EMBODIMENTS

This application relates to methods of charactering a plasma system, more particularly to an in-situ diagnosis of a plasma system. In semiconductor manufacturing, plasma processing is used at various stages for depositing and etching various materials to construct complex structures with precision at nanometer scale. Due to the highly energetic nature of species used in plasma processing, various parts of the plasma system (e.g., a plasma processing chamber wall, electrodes, and focus ring) may experience surface changes over many process cycles of high-volume manufacturing (HVM). For example, some deposits may be formed and build up on the chamber wall from etch byproducts during a plasma process or the electrode and focus ring may wear over time. Another possibility is that parts wear over time or that there are changes to the RF power delivery system; such changes may be due to degradation of RF parts in the power transmission train or to degradation of RF sensors and of control electronics. Both deposits on the walls, parts wear, and changes to the RF delivery system can cause a shift in the process, such as a change in the etch rate. Because these changes in the plasma system are often difficult to predict and risk process failures, preventive maintenance (PM) is periodically performed between plasmas processes followed by qualification of the chamber by etching standard wafers with a standard recipe. However, PM is too costly and cumbersome to perform after every plasma process. Further, post PM qualification may require test wafers and external metrology and is time consuming. As a result, it is currently difficult to assess the changes in the chamber, parts and RF system which result in changes to plasma properties particularly between the preventive maintenance.

Embodiments of the present application disclose the methods of an efficient in-situ diagnosis of the plasma system, where information on the plasmas properties is obtained from sputtering a film, formed over a blank substrate, with chemically inert particles (e.g., argon). The removal rate of the film by sputtering is a sensitive test of the plasma and RF conditions in the chamber. In various embodiments, the removal rate of the film during the sputtering step is characterized with spectroscopic measurements such as optical emission spectroscopy (OES). Embodiments of this application disclose forming a reference film over a blanket wafer, which can be formed in-situ within a plasma chamber in a controlled manner without much process variation. A sputtering process may then be used to sputter the film at a constant rate, which again may be removed in a controlled manner without much process variation. Advantageously, the sputtering process can be implemented to not have a chemical etch component to minimize variation in sputter rate. The elements emitted during the sputtering may be analyzed during the sputtering with a spectroscopic tool to obtain a removal rate of the film. In the absence of chemical etching, the removal rate of the film is dependent only on the plasma chamber and RF plasma conditions. Thus, in various embodiments, periodically obtaining the spectral analysis data across multiple substrates establishes a way to monitor the health of the plasma chamber.

OES is a powerful spectroscopic tool to analyze atoms and ions present in a plasma by detecting optical emission from excited species, and OES systems have been incorporated to some plasma processing systems for process characterization as described in, for example, in U.S. Pat. Nos. 5,862,060 and 10,453,653.

As described with various embodiments below, the inventors of this application identified that the application of OES may be further extended to an in-situ diagnosis of the plasma system used in high-volume manufacturing (HVM). The usability conditions of the plasma chamber, chamber parts, and RF power delivery system may be diagnosed by the methods of this disclosure. The methods of in-situ diagnosis may further include calibration of sensors or updating plasma process parameters based on the diagnosis, which can be useful in preventing drifting and scrap events.

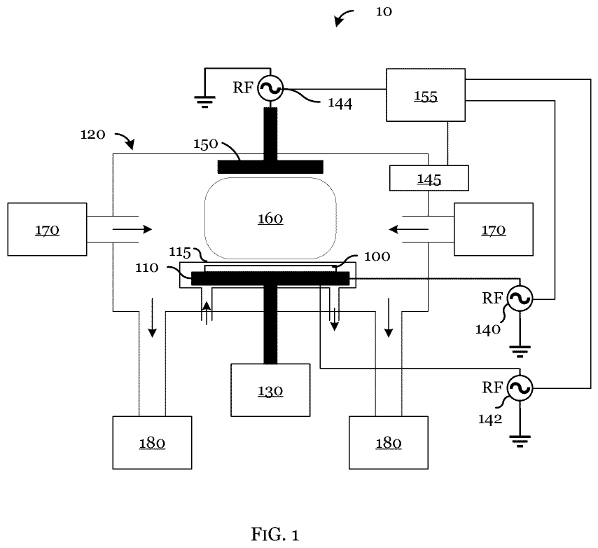

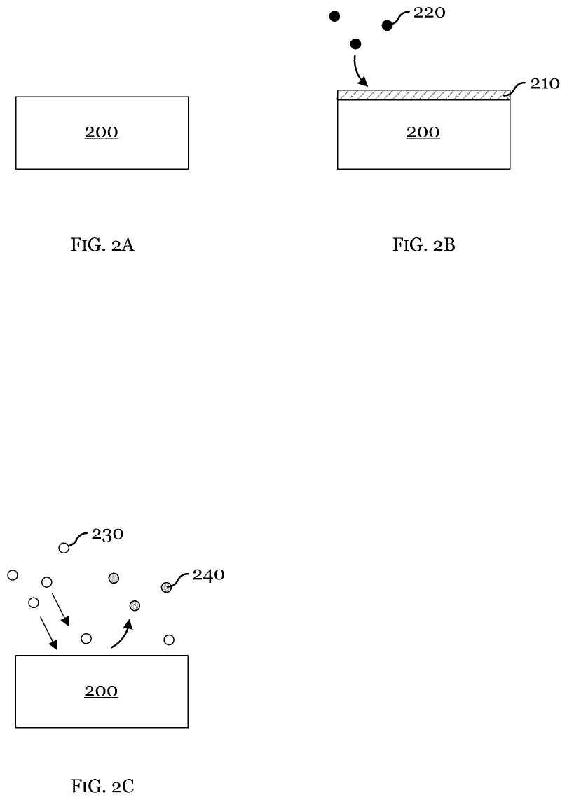

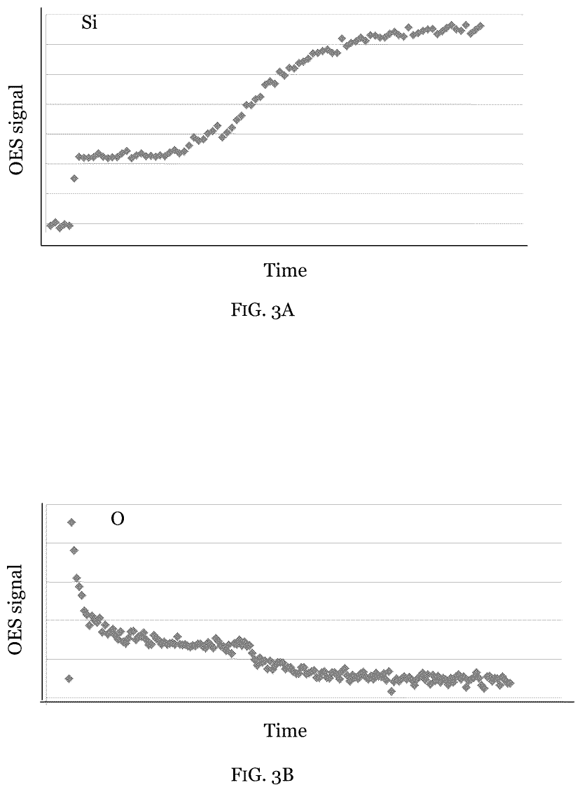

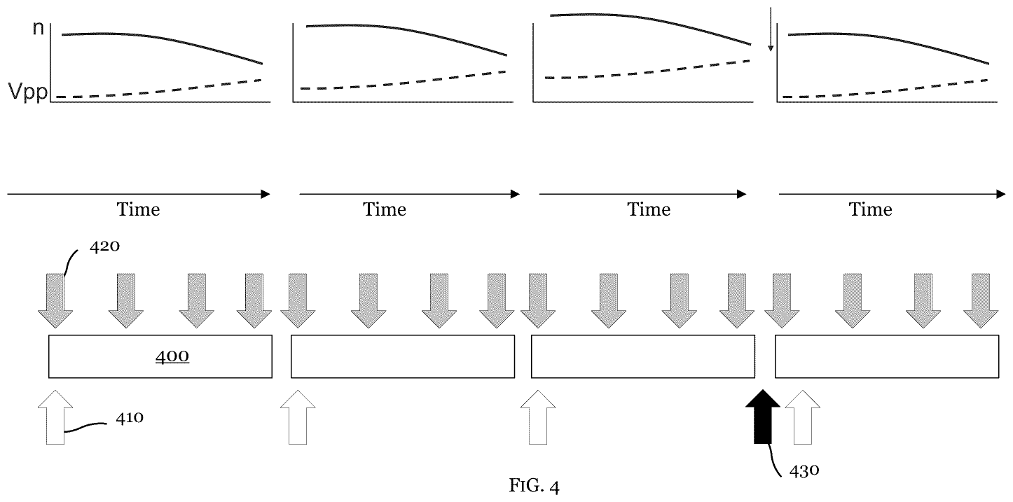

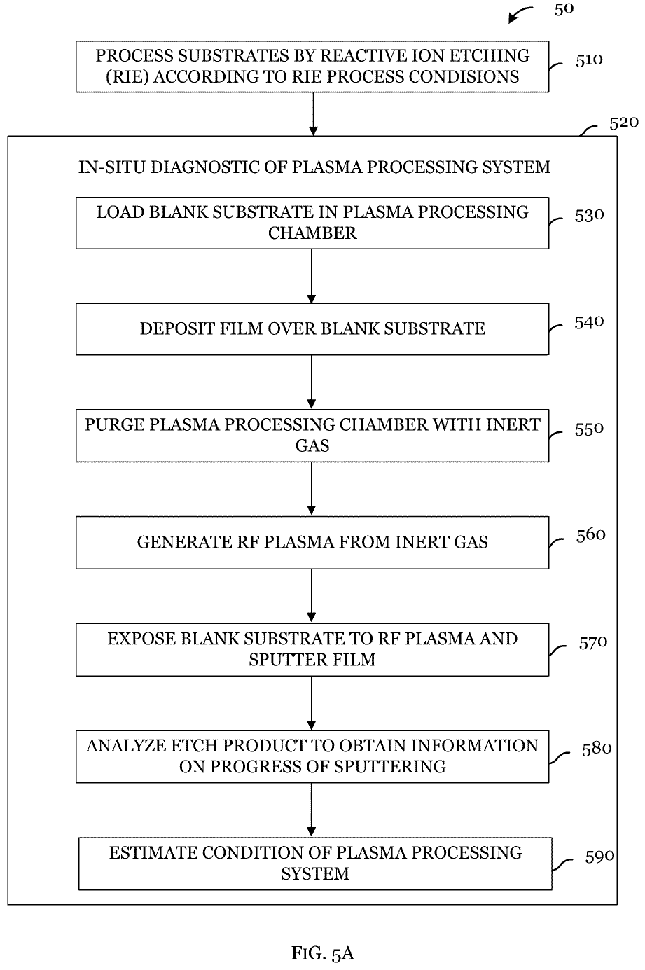

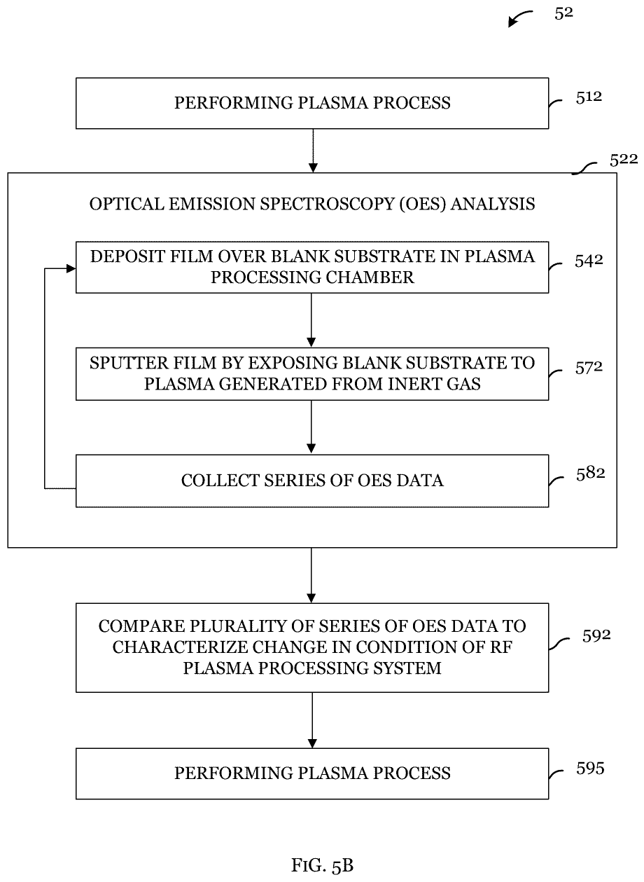

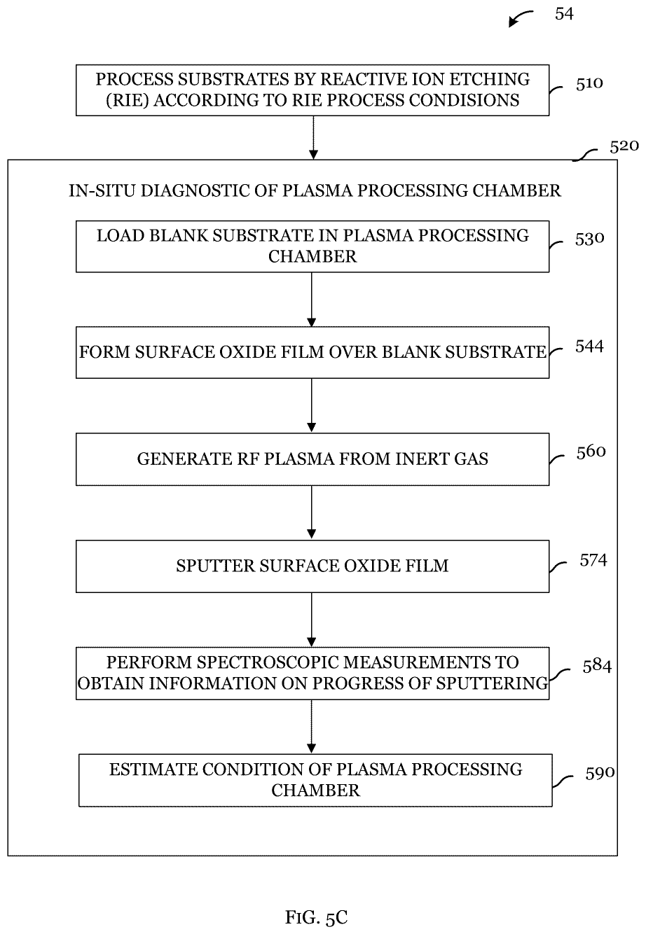

In the following, an example plasma processing system with optical emission spectroscopy (OES) is described referring to FIG. 1. The method of in-situ diagnosis using a blank substrate is described referring to FIGS. 2A-2C. In FIGS. 3A-3B, example temporal profiles of OES signals from a sputtering step in accordance with an embodiment are described. Improvements enabled by the methods in the context of HVM plasma processing are then described referring to an example timing diagram of repeated in-situ diagnosis in FIG. 4. Example process flow diagrams are illustrated in FIGS. 5A-5C. All figures in this disclosure are drawn for illustration purpose only and not to scale.

FIG. 1 illustrates an example plasma processing system 10 with an OES configured to perform an in-situ diagnosis in accordance with various embodiments.

For illustrative purposes, FIG. 1 illustrates a substrate 100 placed on a substrate holder 110 (e.g., a circular electrostatic chuck (ESC)) inside a plasma processing chamber 120 near the bottom. The substrate 100 may be optionally maintained at a desired temperature using a heater/cooler 115 that is directly attached below the substrate holder 110. Alternately, the heater/cooler 115 and the substrate holder 110 may be integrated as a single unit. The temperature of the substrate 100 may be maintained by a temperature controller 130 connected to the substrate holder 110 and the heater/cooler 115. The ESC may be coated with a conductive material (e.g., a carbon-based or metal-nitride based coating) so that electrical connections may be made to the substrate holder 110.

Process gases may be introduced into the plasma processing chamber 120 by a gas delivery system 170. The gas delivery system 170 comprises multiple gas flow controllers to control the flow of multiple gases into the chamber. Each of the gas flow controllers of the gas delivery system 170 may be assigned for each of fluorocarbons, noble gases, and/or balancing agents. In some embodiments, optional center/edge splitters may be used to independently adjust the gas flow rates at the center and edge of the substrate 100. The process gases or any exhaust gases may be evacuated from the plasma processing chamber 120 using vacuum pumps 180.

As illustrated in FIG. 1, the substrate holder 110 may be a bottom electrode of the plasma processing chamber 120. In the illustrative example in FIG. 1, the substrate holder 110 is connected to two RF power sources, 140 and 142. In some embodiment, a conductive circular plate inside the plasma processing chamber 120 near the top is the top electrode 150. In FIG. 1, the top electrode 150 is connected to another RF power source 144 of the plasma processing system 10. In various embodiments, all of power sources for plasma processing (e.g., RF power sources 140, 142, and 144) are connected to a control unit 155 to enable a synchronized operation of the power sources. Further, the control unit 155 is also connected to an OES detection device 145. The OES detection device 145 may be disposed at a position to measure the optical emission from the processing region of a plasma 160 between the substrate 100 and the top electrode 150.

In certain embodiments, power sources may comprise a DC power source. The RF and/or DC power sources (e.g., the RF power sources 140, 142, and 144) may be configured to generate a continuous wave (CW) RF, pulsed RF, DC, pulsed DC, a high frequency rectangular (e.g., square wave) or triangular (e.g., sawtooth) pulse train, or a combination or superposition of more than one such waveform. In addition, power sources may be configured to generate a periodic function, for example, a sinusoid whose characteristics such as amplitude and frequency may be adjusted during a plasma process.

A typical frequency for the RF source power can range from about 0.1 MHz to about 6 GHz. In certain embodiments, the RF power sources 142 and 144 may be used to provide a low frequency RF power and a high frequency RF power at the same time, respectively.

Various configurations may be used for a plasma processing system 10 that is equipped with the OES detection device 145. For example, the plasma processing system 10 may be a capacitively coupled plasma (CCP) system, as illustrated in FIG. 1, or an inductively coupled plasma (ICP) plasma system. In alternate embodiments, the plasma processing system 10 may comprise a resonator such as a helical resonator. Further, microwave plasma (MW) or other suitable systems may also be used. In various embodiments, the RF power, chamber pressure, substrate temperature, gas flow rates and other plasma process parameters may be selected in accordance with the respective process recipe.

The plasma processing system 10 may be used to perform plasma processes to process a large number of substrates, for example, as a part of high-volume manufacturing of semiconductor device. Because the chamber condition and RF power delivery condition may gradually change over process cycles, the plasma process performance may also gradually shift despite the same process recipe (e.g., the RF source power, bias power, and gas composition). The methods of in-situ diagnosis, as further described below, may be used to characterize the chamber and the RF delivery system condition at any point between the plasma processes by measuring a removal rate of a thin film grown on a blank substrate, for example with an optical emission spectroscopy (OES).

FIGS. 2A-2C illustrate cross-sectional views of an example substrate 200 during an in-situ diagnosis comprising in accordance with various embodiments.

FIG. 2A illustrates a cross-sectional view of an incoming blank substrate 200. In various embodiments, the substrate 200 may be a silicon wafer, or a silicon-on-insulator (SOI) wafer. In certain embodiments, the substrate 200 may comprise a silicon germanium wafer, silicon carbide wafer, gallium arsenide wafer, gallium nitride wafer and other compound semiconductors. In other embodiments, the substrate 200 comprises heterogeneous layers such as silicon germanium on silicon, gallium nitride on silicon, silicon carbon on silicon, as well layers of silicon on a silicon or SOI substrate. The substrate 200 may comprise any other suitable material. In certain embodiments, the bulk of the substrate 200 may comprise a metal or metalloid (e.g., Si) and the surface of the substrate 200 may comprise a surface oxide film due to, for example, exposure to atmosphere. Since this surface oxide film may hinder a film growth in the subsequent step, a pretreatment step may be performed (e.g., Ar sputtering) to remove the surface oxide film or any impurities from the surface.

FIG. 2B illustrates a cross-sectional view of the substrate 200 after depositing a film 210.

Over the substrate 200, the film 210 may be formed. In various embodiments, the film 210 may comprise an oxide film (e.g., silicon oxide) and may be formed via surface oxidation induced by exposing the substrate 200 to an O₂ plasma. The surface oxidation may be performed using any suitable oxidative environment in the plasma processing chamber (e.g., O₂, O₃, O₂ plasma, etc.). As illustrated in FIG. 2, oxidative species 220 (e.g., oxygen radical formed in the plasma) may react with the surface of the substrate 200 to form the film 210. In certain embodiments, the exposure time may be between 10 sec and 300 sec. In one embodiment, the surface oxidation may comprise an exposure to a 13 MHz RF plasma generated from a Ar/O₂ mixture (5 sccm/25 sccm) at a source power of 40 W for 60 sec. In other embodiments, any argon-to-oxygen ratio, source power, bias power, and process time may be used. In one embodiment, the surface oxidation may result in the film 210 with a thickness between 1 nm and 20 nm.

In various embodiments, the surface oxidation may be a self-limited process and the growth of the film 210 may essentially stop after reaching to a certain thickness, or the growth rate may substantially decrease to a negligible level. The inventor of this application identified that this self-limited surface reaction is advantageous to reproducibly obtain the same thickness of the film 210 independent of the chamber condition.

FIG. 2C illustrates a cross-sectional view of the substrate 200 after sputtering the film 210.

Subsequently, the film 210 may be removed by sputtering and its removal rate may be evaluated by spectroscopic measurements such as optical emission spectroscopy (OES). The substrate 200 may be exposed to a plasma generated from an inert gas such as argon (Ar) to enable sputtering. In various embodiments, only the inert gas may be used in this step such that the sputtering may be driven only by chemically inert particles 230 as illustrated in FIG. 2C. Etch products 240 may be generated by the sputtering. In certain embodiments, the sputtering time may be between 10 sec and 300 sec. In one embodiment, the sputtering may comprise an exposure to a 13 MHz RF plasma generated from a 1000 sccm Ar at a forward bias power of 200 W at a pressure of 50 mTorr for 90 sec. In other embodiments, other inert gases or any reasonable flow rate, source power, bias power, and process time may be used. In certain embodiments, the sputtering may be continued until the entirety of the film 210 is removed and a portion of the substrate 200 also started to be etched.

The use of inert gas for sputtering may be particularly advantageous for the in-situ diagnosis because if chemically reactive species are involved in the sputtering, they may complicate the etch mechanism of the film 210 and the removal rate may depend on not only the chamber condition and the RF power delivery system, but also on the chemical reactivity of various species present in the plasma system. With the sputtering driven by the chemically inert particles 230, the removal rate may be a function of ion flux and ion energy, which is determined by the plasma process parameters, the chamber condition and the RF power delivery system. Accordingly, comparing two or more of the removal rates for the film 210 with the same sputtering condition at different point of cycles of plasma processes, any change may represent the information on change in the chamber condition.

In further embodiments, the steps of film formation and subsequent sputtering (FIGS. 2B-2C) may be repeated over the substrate 200 or another substrate during the in-situ diagnosis. In certain embodiments, a series of film formation and sputtering may be repeated for the same diagnostic process conditions to improve the accuracy of the in-situ diagnosis by averaging the collected OES data. In other embodiments, each step of sputtering may be performed with varying sputtering conditions, for example, source power, bias power, process time, or chamber pressure. Since the removal rate is expected to show some dependency on the sputtering conditions, analyzing the effect of a particular process parameter on the removal rate during the sputtering may be useful in providing additional information for a usability condition of the plasma system.

In certain embodiments, as a result of sputtering of the film 210, there may be a small amount of deposit (e.g., Si containing) forming on the chamber walls. Since the thickness of the film 210 is relatively small, the amount of deposit may be negligible. In one or more embodiments, an additional clean up step may be inserted after the step of sputtering to remove this deposit to further minimize the impact of the in-situ diagnosis on the chamber conditions. For example, a plasma treatment using oxygen and a fluorine containing gas such as NF₃, CF₄, and SF₆, may be performed as the additional clean up step.

In one or more embodiments, the first set of film formation and sputtering may be performed immediately after a preventive maintenance (PM) and prior to any plasma processes to provide a baseline rate of sputtering for the plasma processing chamber. This baseline rate of sputtering may then be used to examine actual rate of sputtering during the in-situ diagnosis that may be performed during or after a cycle of plasma processes. Any deviation of the actual rate of sputtering from the baseline rate of sputtering may be characterized and used to determine if the chamber and the RF delivery system are still in an acceptable usability condition for processing another substrate or if the chamber or RF delivery system requires some maintenance such as PM.

In certain embodiments, the substrate 200 may comprise silicon (Si) and the film 210 may comprise silicon oxide. Accordingly, the OES measurements may be used to particularly monitor Si and O species in the etch products by the sputtering in order to estimate the removal rate of the film 210. OES may provide advantage of accurate determination of small etch amounts even in case of sputtering a relatively thin film where other analytical tools may not provide sufficient resolution. The application of OES measurements to monitor the removal of silicon oxide from a Si substrate has been experimentally demonstrated by the inventors as described below referring to FIGS. 3A-3B.

FIGS. 3A and 3B illustrate example temporal profiles of OES signals during an in-situ diagnosis in accordance with one embodiment, wherein FIG. 3A illustrates the profile of Si signal, and FIG. 3B illustrates the profile of O signal.

In FIGS. 3A, the OES Si signal is plotted as a function of time. After a short induction period, the intensity of OES Si signal was stable at a first level before transitioning to a higher, second level. This increased in Si amount in the etch product after a certain sputtering time indicates the completion of the removal of silicon oxide and the etching of the Si substrate.

In FIG. 3B, the OES O signal, after a short induction period and a spike, became stable at a first level before transitioning to a lower, second level, corresponding to the completion of the removal of silicon oxide, similar to FIG. 3A.

In various embodiments, the temporal analysis of OES data collected during the sputtering, as illustrated in FIGS. 3A-3B, may be used to determine the rate of removal of the film 210 (e.g., silicon oxide), and by periodically repeating this OES analysis at different stages of cycles of plasma processes, it is possible to obtain the information on the chamber wall and also calibrate RF peak-to-peak voltage (Vₚₚ) to tune the plasma properties (e.g., plasma density) frequently without performing ex-situ examination or time-consuming preventive maintenance (PM).

As described above, the optical emission spectroscopy (OES) may be used to monitor the progress of sputtering (e.g., FIGS. 2C and 3A-3B) as a primary basis for the in-situ diagnosis in various embodiments. In addition, in certain embodiments, OES or other techniques may also be applied during the step of film depositing (e.g., FIG. 2B). For example, OES data may be collected during the deposition step to monitor the density of atomic oxygen, which may then be ensure the film growth (e.g., an oxide film) is consistent between cycles of the in-situ diagnosis. In one or more embodiments, to monitor the film growth, the OES may be replaced or supplemented with other techniques such as in-situ spectroscopic ellipsometer, mass spectroscopy, absorption spectroscopy, laser induced fluorescence, or Fourier-transform infrared (FTIR) spectroscopy.

FIG. 4 illustrates an example timing diagram of repeated in-situ diagnosis during the usage of a plasma processing chamber for plasma processes.

In FIG. 4, the cycles of plasma processes are illustrated together with possible drifting of plasma density (n) and RF Vₚₚ. For illustration, four PM cycles 400 are illustrated, where a PM process may be performed between the PM cycles 400 and each PM cycle 400 may comprise any number of cycles of plasma processes to process a plurality of substrates (e.g., 10-200 cycles). Conventionally, an ex-situ qualification process 410 may be performed after a PM process is performed. This qualification process may ensure the process consistency before performing the next batch of process cycles. The ex-situ qualification process 410, however, typically involves processing a test wafer and relying on external methodology for the characterization, for example cross-sectional scanning electron microscopy (SEM), or spectroscopic ellipsometry, which therefore makes it difficult to perform more frequently. Consequently, any gradual change in chamber condition, drifting, or scrap excursions may not be detected during a PM cycle. Further, the ex-situ qualification process 410 that involves reactive ion etching (RIE) inherently suffers from the difficulty of decoupling the various contributing factors to the process and its diagnosis may be non-specific. For example, wall coatings and drift of the RF power delivery system may both result in changes in the reactive ion etching rate of a substrate. The use of more frequent, in-situ diagnosis 420 as described above in various embodiments may advantageously supplement the conventional diagnostic method.

As further illustrated in FIG. 4, during the cycles of plasma processes, plasma density (n) and RF Vₚₚ may drift gradually due to the change in plasma processing chamber condition. The drifting may be monitored using a VI sensor connected to the plasma system. The in-situ diagnosis 420 may advantageously improve this monitoring by providing additional data and also enabling frequent calibration of the VI sensors. When the drifting exceeds the acceptable level, a next PM process can include an additional step, such as chamber part replacement 430 to replacing one or more appropriate chamber parts. This is illustrated between the third and fourth PM cycles 400 in FIG. 4.

In one example, the in-situ diagnosis 420 may provide information on drifts in the RF power delivery system. For example, if the sputter rate determined by the in-situ diagnosis 420 remains the same over a PM period, while the VI sensors show that Vₚₚ is changing, this trend signifies that either one or more of the sensors are drifting or that there is a drift in other parts that may be compensating for the Vₚₚ drift, resulting in the constant sputter rate; both possibilities may signal a need for further investigation in order to prevent a possible inconsistency during the cycles of plasma processes.

In certain embodiments, RF Vₚₚ and plasma density may be tuned based on a machine learning (ML) model during the plasma processes, and the ML model maybe fed with VI sensor data. The data from the in-situ diagnosis 420 (e.g., OES data) may also be used as additional data to the ML model to improve the robustness of the model.

The in-situ diagnosis 420, as described above, may be non-destructive and relatively rapid, which can be performed more frequently than conventional time-consuming diagnostic methods. Although only four arrows are illustrated for the in-situ diagnosis 420 per PM cycle 400, in various embodiments, the number of the in-situ diagnosis 420 per PM cycle 400 is not limited to any number. By performing the in-situ diagnosis 420 frequently during one PM cycle 400, the methods enable tuning the recipe for the plasma processes more often to account for the effect of drifting of RF Vₚₚ and plasma density. Further, the methods may improve the chance of detecting scrap excursions.

Although this disclosure primarily describes the method of in-situ diagnosis using optical emission spectroscopy (OES) to monitor the etch products from the sputtering, other appropriate analytical tools may also be used in the methods in place of, or in addition to, OES. Further, the surface of the bulk substrate may also be characterized to monitor the progress of sputtering in place of, or in addition to, the etch products. In one embodiment, Fourier-transform infrared spectroscopy (FTIR) may be used to monitor the surface of the blank substrate.

FIGS. 5A-5C illustrate process flow charts of methods of in-situ diagnosis of plasma system in accordance with various embodiments. The process flow can be followed with the figures (FIGS. 2A-2C and 4) discussed above and hence will not be described again.

In FIG. 5A, a process flow 50 starts with processing a series of substrates using a plasma processing system having a plasma processing chamber by reactive ion etching (RIE) according to a RIE process condition (block 510), and after the processing, an in-situ diagnosis of the plasma processing system may be performed (block 520, FIGS. 2A-2C). The in-situ diagnosis may start with loading a blank substrate in the plasma processing chamber (block 530, FIG. 2A). Next, a film may be deposited over the blank substrate (block 540, FIG. 2B), followed by purging the plasma processing chamber with an inert gas (block 550). A RF plasma may then be generated in the plasma from the inert gas according to a diagnostic process condition (block 560). The film may be sputtered by exposing the blank substrate to the RF plasma (block 570, FIG. 2C). During the sputtering, the etch product may be analyzed to obtain information on a progress of the sputtering (block 580), for example, using an optical emission spectroscopy (OES) measurement. Based on the information on the progress of the sputtering, a condition of the plasma processing system may be estimated (block 590).

In FIG. 5B, another process flow 52 starts with performing plasma processes to process a set of substrates using a RF plasma processing system having a plasma processing chamber and a RF power delivery system (block 512), where the plasma processes are temporally separated to each other by intervals. During some of the intervals, an optical emission spectroscopy (OES) analysis may be periodically repeated (block 522, FIGS. 2B-2C). Each OES analysis may comprise depositing a film over a blank substrate loaded in the plasma processing chamber (block 542, FIG. 2B), followed by sputtering the film by exposing the blank substrate to a plasma generated from an inert gas (block 572, FIG. 2C). While exposing the blank substrate to the plasma, a series of OES data may be collected. In various embodiments, these steps of film deposition, sputtering, and OES data collection may be repeated to generate a plurality of the series of OES data. Subsequently, the plurality of the series of OES data may then be compared to characterize a change in a condition of the RF plasma processing system during the plasma processes (block 592). In certain embodiments, depending on the result of the OES analysis, a plasma process recipe may be updated to account for the change in the condition of the RF plasma processing system or determine if a preventive maintenance (PM) may be necessary. If the PM is determined to be necessary, it may be performed before continuing the plasma processes. After the OES analysis, the plasma processes may be continued to process a next batch of substrates (block 595).

In FIG. 5C, yet another process flow 54 starts with processing a series of substrates in a plasma processing chamber by reactive ion etching (RIE) according to a RIE process condition (block 510), and after the processing, an in-situ diagnosis of the plasma processing chamber may be performed (block 520, FIGS. 2A-2C). The in-situ diagnosis may start with loading a blank substrate in the plasma processing chamber (block 530, FIG. 2A). Next, a surface oxide film may be formed over the blank substrate (block 544, FIG. 2B), followed by generating a RF plasma in the plasma from a gas comprising an inert gas according to a diagnostic process condition (block 560). The surface oxide film may be sputtered by exposing the blank substrate to the RF plasma (block 574, FIG. 2C). During the sputtering, spectroscopic measurements may be performed to obtain information on a progress of the sputtering (block 584). Based on the information on the progress of the sputtering, a condition of the plasma processing chamber may be estimated (block 590).

Example embodiments of the invention are summarized here. Other embodiments can also be understood from the entirety of the specification as well as the claims filed herein.

Example 1. A method for processing a substrate that includes: processing a series of substrates using a plasma processing system having a plasma processing chamber by reactive ion etching (RIE) according to a RIE process condition; and after the processing, performing an in-situ diagnosis of the plasma processing system, the in-situ diagnosis including loading a substrate in the plasma processing chamber, depositing a film over the substrate, purging the plasma processing chamber with an inert gas, generating a RF plasma in the plasma processing chamber from the inert gas, sputtering the film to generate an etch product, the sputtering including exposing the substrate to the RF plasma, determining a rate of the sputtering of the film, and based on the rate of the sputtering of the film, determining a usability condition of the plasma processing system for processing another substrate.

Example 2. The method of example 1, further including: based on the usability condition determined during the in-situ diagnosis, updating the RIE process condition; and processing another series of substrates by the RIE according to the updated RIE process condition.

Example 3. The method of one of examples 1 or 2, further including, based on the usability condition determined during the in-situ diagnosis, generating a control signal indicative of a preventive maintenance for the plasma processing system.

Example 4. The method of one of examples 1 to 3, where sputtering the film is performed according to a diagnostic process condition, and where the in-situ diagnosis further includes: after sputtering the film, redepositing the film over the substrate, the redeposited film having a same thickness as the film; updating the diagnostic process condition by changing a process parameter; sputtering the redeposited film according to the updated diagnostic process condition; determining a rate of the sputtering of the redeposited film; and comparing the rate of the sputtering of the film and the rate of the sputtering of the redeposited film to determine an effect of the process parameter on an etch rate of the RIE.

Example 5. The method of one of examples 1 to 4, where the in-situ diagnosis further includes, prior to depositing the film, exposing the substrate to another RF plasma to clean a surface of the substrate.

Example 6. The method of one of examples 1 to 5, where the film includes an element that is not present in the substrate, and where determining the rate of the sputtering of the film includes monitoring the element in the etch product.

Example 7. The method of one of examples 1 to 6, where the film includes an oxide and the element is oxygen.

Example 8. The method of one of examples 1 to 7, where depositing the film includes exposing the substrate to an oxygen plasma.

Example 9. The method of one of examples 1 to 8, where determining the rate of the sputtering of the film includes: while sputtering the film, collecting a series of optical emission spectra (OES) from the etch product; and performing a temporal analysis of the series of OES to determine the rate of the sputtering of the film.

Example 10. The method of one of examples 1 to 9, where the film includes an oxide, where the substrate includes silicon (Si), and where the series of OES includes oxygen spectra and Si spectra.

Example 11. The method of one of examples 1 to 10, where the inert gas includes argon (Ar).

Example 12. A method for processing a substrate that includes: performing plasma processes to process a set of substrates using a RF plasma processing system having a plasma processing chamber and a RF power delivery system, the plasma processes are temporally separated to each other by intervals; during some of the intervals, periodically repeating an optical emission spectroscopy (OES) analysis, each OES analysis including depositing a film over a substrate loaded in the plasma processing chamber, sputtering the film by exposing the substrate to a plasma generated from an inert gas, and while exposing the substrate to the plasma, collecting a series of OES data, where repeating the OES analysis generates a plurality of the series of OES data, and comparing the plurality of the series of OES data to characterize a change in a usability condition of the RF plasma processing system during the plasma processes.

Example 13. The method of example 12, where each OES analysis further includes: prior to depositing the film, exposing the substrate to an argon (Ar) plasma to clean the substrate; and repeating depositing the film and sputtering the film as a cyclic process, where a process condition for the sputtering is changed for each cycle of the cyclic process.

Example 14. The method of one of examples 12 or 13, where each OES analysis further includes determining a rate of the sputtering based on the series of OES data.

Example 15. The method of one of examples 12 to 14, where the film includes silicon oxide, where the substrate includes silicon (Si), where the inert gas includes argon (Ar), and where the series of OES includes oxygen spectra.

Example 16. The method of one of examples 12 to 15, where the usability condition of the RF plasma processing system includes a condition of the plasma processing chamber or that of the RF power delivery system.

Example 17. A method for processing a substrate that includes: processing a series of substrates in a plasma processing chamber by reactive ion etching (RIE) according to a RIE process condition; and after the processing, performing an in-situ diagnosis of the plasma processing chamber, the in-situ diagnosis including providing a baseline rate of sputtering for the plasma processing chamber, loading a substrate in the plasma processing chamber, forming a surface oxide film over the substrate, generating a RF plasma in the plasma from a gas including an inert gas according to a diagnostic process condition, sputtering the surface oxide film, the sputtering including exposing the substrate to the RF plasma, while sputtering the surface oxide film, performing spectroscopic measurements to determine an actual rate of the sputtering of the surface oxide film, and based on a variance between the baseline rate of sputtering and the actual rate of sputtering, determining a usability condition of the plasma processing chamber for processing another substrate.

Example 18. The method of example 17, further including: based on the usability condition determined during the in-situ diagnosis, updating the RIE process condition; and processing another series of substrates by the RIE according to the updated RIE process condition.

Example 19. The method of one of examples 17 or 18, further including, based on the usability condition determined during the in-situ diagnosis, generating a control signal indicative of a preventive maintenance for the plasma processing chamber.

Example 20. The method of one of examples 17 to 19, where the plasma processing chamber is kept under vacuum and not exposed to atmosphere between the processing and the in-situ diagnosis of the plasma processing chamber.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a substrate, the method comprising:
processing a series of substrates using a plasma processing system having a plasma processing chamber by reactive ion etching (RIE) according to a RIE process condition; and
after the processing, performing an in-situ diagnosis of the plasma processing system, the in-situ diagnosis comprising
loading a substrate in the plasma processing chamber,
depositing a film over the substrate,
purging the plasma processing chamber with an inert gas,
generating a RF plasma in the plasma processing chamber from the inert gas,
sputtering the film to generate an etch product, the sputtering comprising exposing the substrate to the RF plasma,
determining a rate of the sputtering of the film, and
based on the rate of the sputtering of the film, determining a usability condition of the plasma processing system for processing another substrate.

2. The method of claim 1, further comprising:
based on the usability condition determined during the in-situ diagnosis, updating the RIE process condition; and
processing another series of substrates by the RIE according to the updated RIE process condition.

3. The method of claim 1, further comprising, based on the usability condition determined during the in-situ diagnosis, generating a control signal indicative of a preventive maintenance for the plasma processing system.

4. The method of claim 1, wherein sputtering the film is performed according to a diagnostic process condition, and wherein the in-situ diagnosis further comprises:
after sputtering the film, redepositing the film over the substrate, the redeposited film having a same thickness as the film;
updating the diagnostic process condition by changing a process parameter;
sputtering the redeposited film according to the updated diagnostic process condition;
determining a rate of the sputtering of the redeposited film; and
comparing the rate of the sputtering of the film and the rate of the sputtering of the redeposited film to determine an effect of the process parameter on an etch rate of the RIE.

5. The method of claim 1, wherein the in-situ diagnosis further comprises, prior to depositing the film, exposing the substrate to another RF plasma to clean a surface of the substrate.

6. The method of claim 1, wherein the film comprises an element that is not present in the substrate, and wherein determining the rate of the sputtering of the film comprises monitoring the element in the etch product.

7. The method of claim 6, wherein the film comprises an oxide and the element is oxygen.

8. The method of claim 7, wherein depositing the film comprises exposing the substrate to an oxygen plasma.

9. The method of claim 1, wherein determining the rate of the sputtering of the film comprises:
while sputtering the film, collecting a series of optical emission spectra (OES) from the etch product; and
performing a temporal analysis of the series of OES to determine the rate of the sputtering of the film.

10. The method of claim 9, wherein the film comprises an oxide, wherein the substrate comprises silicon (Si), and wherein the series of OES comprises oxygen spectra and Si spectra.

11. The method of claim 1, wherein the inert gas comprises argon (Ar).

12. A method for processing a substrate, the method comprising:
performing plasma processes to process a set of substrates using a RF plasma processing system having a plasma processing chamber and a RF power delivery system, the plasma processes are temporally separated to each other by intervals;
during some of the intervals, periodically repeating an optical emission spectroscopy (OES) analysis, each OES analysis comprising
depositing a film over a substrate loaded in the plasma processing chamber,
sputtering the film by exposing the substrate to a plasma generated from an inert gas, and
while exposing the substrate to the plasma, collecting a series of OES data, wherein repeating the OES analysis generates a plurality of the series of OES data, and
comparing the plurality of the series of OES data to characterize a change in a usability condition of the RF plasma processing system during the plasma processes.

13. The method of claim 12, wherein each OES analysis further comprises:
prior to depositing the film, exposing the substrate to an argon (Ar) plasma to clean the substrate; and
repeating depositing the film and sputtering the film as a cyclic process, wherein a process condition for the sputtering is changed for each cycle of the cyclic process.

14. The method of claim 12, wherein each OES analysis further comprises determining a rate of the sputtering based on the series of OES data.

15. The method of claim 12, wherein the film comprises silicon oxide, wherein the substrate comprises silicon (Si), wherein the inert gas comprises argon (Ar), and wherein the series of OES comprises oxygen spectra.

16. The method of claim 12, wherein the usability condition of the RF plasma processing system comprises a condition of the plasma processing chamber or that of the RF power delivery system.

17. A method for processing a substrate, the method comprising:
processing a series of substrates in a plasma processing chamber by reactive ion etching (RIE) according to a RIE process condition; and
after the processing, performing an in-situ diagnosis of the plasma processing chamber, the in-situ diagnosis comprising
providing a baseline rate of sputtering for the plasma processing chamber,
loading a substrate in the plasma processing chamber,
forming a surface oxide film over the substrate,
generating a RF plasma in the plasma from a gas comprising an inert gas according to a diagnostic process condition,
sputtering the surface oxide film, the sputtering comprising exposing the substrate to the RF plasma,
while sputtering the surface oxide film, performing spectroscopic measurements to determine an actual rate of the sputtering of the surface oxide film, and
based on a variance between the baseline rate of sputtering and the actual rate of sputtering, determining a usability condition of the plasma processing chamber for processing another substrate.

18. The method of claim 17, further comprising:
based on the usability condition determined during the in-situ diagnosis, updating the RIE process condition; and
processing another series of substrates by the RIE according to the updated RIE process condition.

19. The method of claim 17, further comprising, based on the usability condition determined during the in-situ diagnosis, generating a control signal indicative of a preventive maintenance for the plasma processing chamber.

20. The method of claim 17, wherein the plasma processing chamber is kept under vacuum and not exposed to atmosphere between the processing and the in-situ diagnosis of the plasma processing chamber.
